(19) United States
(12) Patent Application Publication
(10) Pub. No.: US 2024/0363798 A1
(43) Pub. Date: Oct. 31, 2024

(54) LIGHT-EMITTING DIODE CHIP, MANUFACTURING METHOD THEREOF AND DISPLAY APPARATUS

(71) Applicant: BOE TECHNOLOGY GROUP CO., LTD., Beijing (CN)

(72) Inventors: Jingjing ZHANG, Beijing (CN); Can ZHANG, Beijing (CN); Can WANG, Beijing (CN); Wei LI, Beijing (CN); Jinfei NIU, Beijing (CN); Ning CONG, Beijing (CN)

(21) Appl. No.: 18/028,791

(22) PCT Filed: Apr. 25, 2022
(86) PCT No.: PCT/CN2022/088982

§ 371 Date: Mar. 28, 2023

(51) Int. Cl. H01L 33/20; H01L 33/38; H01L 33/50; H01L 33/62

(52) U.S. Cl. CPC H01L 33/20; H01L 33/382; H01L 33/505; H01L 33/62; H01L 2933/0016; H01L 2933/0041

(57) ABSTRACT

A light-emitting diode chip includes: epitaxial structures on one side of substrate, a gap existing between any two adjacent epitaxial structures, first semiconductor patterns of epitaxial structures coupled to form first semiconductor layer; first light-blocking layer on a side of the first semiconductor layer away from substrate, first light-blocking layer having accommodating holes in one-to-one correspondence with epitaxial structures, the light-emitting patterns and the second semiconductor patterns of epitaxial structures being in accommodating holes; second light-blocking layer on a side of first light-blocking layer away from substrate, second light-blocking layer having pixel openings in one-to-one correspondence with accommodating holes; orthographic projections of pixel opening and corresponding accommodating hole on substrate overlap with each other; light processing pattern is in at least one pixel opening; light processing pattern includes color conversion pattern configured to convert light of preset color emitted by light-emitting pattern into light of other color.

### TECHNICAL FIELD

The present disclosure relates to the field of display technology, in particular to a light-emitting diode chip, a method for manufacturing a light-emitting diode chip and a display apparatus.

### BACKGROUND

A light-emitting diode (LED) chip has many advantages such as high efficiency, high brightness, high reliability, energy saving, and fast response speed. Compared with a liquid crystal display (LCD) display apparatus and an organic light-emitting diode (OLED) display apparatus, an LED display apparatus has obvious advantages in image quality, refresh frequency, power consumption, and brightness, so that the LED display apparatus is widely applied to the fields of conventional display, near-to-eye display, 3D (3-dimensional) display, and transparent display.

### SUMMARY

In a first aspect, an embodiment of the present disclosure provides a light-emitting diode chip, including: a substrate; a plurality of epitaxial structures on a side of the substrate, wherein a gap exists between any two adjacent epitaxial structures, each epitaxial structure includes a first semiconductor pattern, a light-emitting pattern and a second semiconductor pattern which are sequentially stacked, and the first semiconductor patterns of the plurality of epitaxial structures are coupled to each other to form a first semiconductor layer; a first light-blocking layer on a side of the first semiconductor layer away from the substrate, wherein the first light-blocking layer is provided therein with a plurality of accommodating holes in one-to-one correspondence with the plurality of epitaxial structures, and the light-emitting patterns and the second semiconductor patterns of the plurality of epitaxial structures are in the corresponding accommodating holes; a second light-blocking layer on a side of the first light-blocking layer away from the substrate, wherein the second light-blocking layer is provided therein with a plurality of pixel openings in one-to-one correspondence with the plurality of accommodating holes; an orthographic projection of each pixel opening on the substrate overlaps with an orthographic projection of the corresponding accommodating hole on the substrate; a light processing pattern is in at least one pixel opening and includes a color conversion pattern configured to convert light of a preset color emitted by the light-emitting pattern into light of other color; at least one first electrode electrically coupled to the first semiconductor layer; and a plurality of second electrodes in one-to-one correspondence with the plurality of epitaxial structures and electrically coupled to the second semiconductor patterns of the corresponding epitaxial structures.

In some embodiments, the first light-blocking layer and the second light-blocking layer have one-piece structure.

In some embodiments, the orthographic projection of each pixel opening on the substrate completely covers the orthographic projection of the corresponding accommodating hole on the substrate.

In some embodiments, the at least one first electrode is on a side of the second light-blocking layer away from the substrate, and is coupled to and in contact with the first semiconductor layer in a via manner.

In some embodiments, each epitaxial structure further includes an ohmic contact pattern on the side of the second semiconductor pattern away from the substrate, the ohmic contact pattern is in the corresponding accommodating hole; and the plurality of second electrodes are on a side of the second light-blocking layer away from the substrate, and each second electrode is coupled to and in contact with the ohmic contact pattern of the corresponding epitaxial structure in a via manner.

In some embodiments, the light processing pattern is in each pixel opening; and wherein the light processing pattern in a part of the plurality of pixel openings is the color conversion pattern, and the light processing pattern in other part of the plurality of pixel openings is a light-transmitting pattern configured to allow light of the preset color to pass therethrough.

In some embodiments, the first electrode is in contact with the first semiconductor layer through a first connection hole in the first light-blocking layer and the second light-blocking layer; and each second electrode is in contact with the ohmic contact pattern of the corresponding epitaxial structure through a second connection hole in the corresponding light processing pattern.

In some embodiments, the at least one first electrode and the plurality of second electrodes are in a same layer.

In some embodiments, the light of the preset color is blue light; and the light of other color includes at least one of red light, green light, cyan light, magenta light, and yellow light.

In some embodiments, the substrate includes a first region and a second region along a second direction; the at least one first electrode is in the first region; the plurality of epitaxial structures are in the second region and are sequentially arranged in the second region along a first direction; the plurality of pixel openings corresponding to the plurality of epitaxial structures are in the second region and are sequentially arranged in the second region along the first direction; and an orthographic projection of each second electrode on the substrate overlaps with an orthographic projection of the pixel opening of the corresponding epitaxial structure on the substrate, and the orthographic projection of each second electrode on the substrate is at one end, which is close to the first region, of the orthographic projection of the pixel opening of the corresponding epitaxial structure on the substrate.

In some embodiments, the at least one first electrode includes one first electrode at a middle position of the first region in the first direction; the plurality of pixel openings corresponding to the plurality of epitaxial structures are arranged at equal intervals along the first direction in the second region; and the plurality of second electrodes corresponding to the plurality of epitaxial structures are arranged at equal intervals along the first direction in the second region.

In some embodiments, a length of each light-emitting pattern in the first direction is in a range from 10 μm to 100 μm; and a length of each light-emitting pattern in the second direction is in a range from 30 μm to 200 μm.

In a second aspect, an embodiment of the present disclosure further provides a method for manufacturing a light emitting diode chip, where the method is used to manufacture the light emitting diode chip provided in the first aspect, and the method includes: providing the substrate; forming the plurality of epitaxial structures, the first light-blocking layer, and the second light-blocking layer on one side of the substrate; wherein a gap exists between any two adjacent epitaxial structures, each epitaxial structure includes the first semiconductor pattern, the light-emitting pattern and the second semiconductor pattern which are sequentially stacked, and the first semiconductor patterns of the plurality of epitaxial structures are coupled to each other to form the first semiconductor layer; the first light-blocking layer is on a side of the first semiconductor layer away from the substrate, and is provided therein with the plurality of accommodating holes in one-to-one correspondence with the plurality of epitaxial structures, and the light-emitting patterns and the second semiconductor patterns of the plurality of epitaxial structures are in corresponding ones of the plurality of accommodating holes; the second light-blocking layer is on a side of the first light-blocking layer away from the substrate, and is provided therein with the plurality of pixel openings in one-to-one correspondence with the plurality of accommodating holes; an orthographic projection of each pixel opening on the substrate overlaps with an orthographic projection of the corresponding accommodating hole on the substrate; forming the light processing pattern in at least one pixel opening; wherein the at least one light processing pattern includes a color conversion pattern configured to convert light of a preset color emitted by the light-emitting pattern into light of other color; forming the at least one first electrode, wherein the at least one first electrode is electrically coupled to the first semiconductor layer; and forming the plurality of second electrodes, wherein the plurality of second electrodes are in one-to-one correspondence with the plurality of epitaxial structures, and are electrically coupled to the second semiconductor patterns of the corresponding epitaxial structures.

In some embodiments, the light-emitting diode chip is the above light-emitting diode chip, and the forming the plurality of epitaxial structures, the first light-blocking layer, and the second light-blocking layer on a side of the substrate, includes: forming the first semiconductor layer; forming the first light-blocking layer and the second light-blocking layer on a side of the first semiconductor layer away from the substrate through one patterning process, wherein the plurality of accommodating holes in one-to-one correspondence with the plurality of epitaxial structures are formed in the first light-blocking layer, the plurality of pixel openings in one-to-one correspondence with the plurality of epitaxial structures are formed in the second light-blocking layer, and the pixel openings are communicated with the corresponding accommodating holes; sequentially forming the light-emitting pattern and the second semiconductor pattern in each accommodating hole; and forming the light processing pattern in at least one pixel opening.

In some embodiments, the light processing pattern is in each pixel opening; and a part of the light processing patterns is the color conversion pattern, and other part of the light processing patterns is light-transmitting pattern configured to allow the light of the preset color to pass therethrough; and the forming the light processing pattern within at least one pixel opening, includes: forming the color conversion pattern in a part of the plurality of pixel openings, and forming the light-transmitting pattern in other part of the plurality of pixel openings.

In some embodiments, in the forming the first light-blocking layer and the second light-blocking layer on the side of the first semiconductor layer away from the substrate through one patterning process, a first connection holes communicated with the first semiconductor layer is formed in the first light-blocking layer and the second light-blocking layer; after the forming the second semiconductor pattern in each accommodating hole and before the forming the light processing pattern in each pixel opening, the method further includes: forming an ohmic contact pattern on a side of the second semiconductor pattern away from the substrate in each accommodating hole; after the forming the light processing pattern in each pixel opening, the method further includes: etching a part of each light processing pattern to form a second connection hole coupled to the ohmic contact pattern; and the forming the at least one first electrode and the forming the plurality of second electrodes include: forming the at least one first electrode and the plurality of second electrodes on a side of the second light-blocking layer away from the substrate through one patterning process, wherein the at least one first electrode is in contact with the first semiconductor layer through the first connection hole, and each second electrode is in contact with a corresponding one of the plurality of second semiconductor patterns through the second connection hole.

In a third aspect, an embodiment of the present disclosure further provides a display apparatus, including: a driving back plate including a plurality of connection pads, wherein the plurality of connection pads include a plurality of first pads and a plurality of second pads; and a plurality of light-emitting diode chips, wherein each light-emitting diode chip is the light-emitting diode chip according to any one of the above embodiments, each first electrode of the light-emitting diode chip is electrically coupled to a corresponding one of the plurality of first pads, and each second electrode of the light-emitting diode chip is electrically coupled to a corresponding one of the plurality of second pads.

In some embodiments, each first electrode and each second electrode are on a side of the second light-blocking layer away from the driving back plate; each first electrode is coupled to the corresponding first pad through a first conductive lead; and each second electrode is coupled to the corresponding second pad through a second conductive lead.

In some embodiments, the display apparatus further includes: a third light-blocking layer between any two adjacent light-emitting diode chips; and an encapsulation layer on a side of the third light-blocking layer and the light-emitting diode chips away from the driving back plate.

### BRIEF DESCRIPTION OF DRAWINGS

FIG. 1 is a schematic top view of an LED chip according to an embodiment of the present disclosure;

FIG. 2 is a schematic cross-sectional view taken along a line A-A′ of FIG. 1;

FIG. 3 is a schematic cross-sectional view taken along a line B-B′ of FIG. 1;

FIG. 4 is a schematic cross-sectional view taken along a line C-C′ of FIG. 1;

FIG. 5 is a schematic diagram showing a size of an LED chip according to an embodiment of the present disclosure;

FIG. 6 is a flowchart of a method for manufacturing an LED chip according to an embodiment of the present disclosure;

FIG. 7 is a flowchart of another method for manufacturing an LED chip according to an embodiment of the present disclosure;

FIGS. 8a to 8d are schematic cross-sectional views of intermediate products obtained by using the manufacturing method shown in FIG. 7;

FIGS. 9b to 9d are schematic cross-sectional views of intermediate products obtained by using the manufacturing method shown in FIG. 7; and

FIG. 10 is a schematic cross-sectional view of a display apparatus according to an embodiment of the present disclosure.

### DETAIL DESCRIPTION OF EMBODIMENTS

In order to enable one of ordinary skill in the art to better understand the technical solutions of the present disclosure, a light-emitting diode chip, a method for manufacturing a light-emitting diode chip and a display apparatus will be described in further detail with reference to the accompanying drawings.

In order to enable one of ordinary skill in the art to better understand the technical solutions of the present disclosure, a light-emitting diode chip, a method for manufacturing a light-emitting diode chip and a display apparatus will be described in further detail with reference to the accompanying drawings.

The technical solutions in some embodiments of the present disclosure will be clearly and completely described below with reference to the accompanying drawings, and it is to be understood that the described embodiments are only a part of the embodiments of the present disclosure, and not all of the embodiments. All other embodiments, which are obtained by a person of ordinary skill in the art based on the embodiments according to the present disclosure, are within the scope of protection of the present disclosure.

Unless the context requires otherwise, throughout the specification and the claims, the word “comprise” and its other forms, such as the third person singular form “comprises” and the present participle form “comprising”, will be interpreted as open, inclusive meaning, that is, “including, but not limited to”. In the description of the specification, the terms “one embodiment”, “some embodiments”, “exemplary embodiments”, “example”, “specific example” or “some examples” and the like are intended to indicate that a particular feature, structure, material, or characteristic described in connection with the embodiment or example is included in at least one embodiment or example of the present disclosure. The schematic representations of the terms used above do not necessarily refer to the same embodiment or example. Furthermore, the particular features, structures, materials, or characteristics may be included in any suitable manner in any one or more embodiments or examples.

In the following, the terms “first”, “second” and the like are used for descriptive purposes only and are not to be understood as indicating or implying relative importance or implicitly indicating the number of technical features indicated. Thus, a feature defined by using the “first”, “second” and the like may explicitly or implicitly include one or more of that features. In the description of the embodiments of the present disclosure, “a plurality of . . . ” means two or more, unless otherwise specified.

In describing some embodiments, the expression “coupled” and derivatives thereof may be used. For example, the term “coupled” may be used in describing some embodiments to indicate that two or more elements are in direct physical or electrical contact with each other. The embodiments disclosed herein are not necessarily limited to the contents herein.

“At least one of A, B and C” and “at least one of A, B or C” have the same meaning and include the following combinations of A, B and C: A alone, B alone, C alone, a combination of A and B, a combination of A and C, a combination of B and C, and a combination of A, B and C. “A and/or B” includes the following three combinations: A alone, B alone, and a combination of A and B.

The use of “adapted to” or “configured to” herein means open and inclusive language that does not exclude devices adapted to or configured to perform additional tasks or steps.

As used herein, “about” or “approximately” includes the stated value as well as an average value within a range of acceptable deviations for the particular value. The range of acceptable deviations is determined by the measurement in discussion and an error associated with the measurement having a particular quantity (i.e., the limitations of the system for the measurement) considered by one of ordinary skill in the art.

Example embodiments are described herein with reference to cross-sectional and/or plan views as idealized example drawings. In the drawings, thicknesses of layers and regions are exaggerated for clarity. Therefore, for example, variations of the shapes with respect to the drawings of caused by the manufacturing techniques and/or tolerances are envisaged. Thus, example embodiments should not be construed as being limited to the shapes of regions illustrated herein but are to include deviations in shapes caused by the manufacturing process. For example, an etched region shown as a rectangle will typically have curved features. Thus, the regions illustrated in the drawings are schematic in nature and their shapes are not intended to illustrate the actual shape of a region of a device and are not intended to limit the scope of exemplary embodiments.

The LED display apparatus generally includes a driving substrate and a plurality of LED chips electrically coupled to the driving substrate. The plurality of LED chips are generally transferred onto the driving substrate by mass transfer technology. In the related art, each LED chip only has one epitaxial structure, each LED chip may serve as a sub-pixel (or a subpixel) of a display apparatus. In order to implement a display apparatus with a corresponding resolution, the number of sub-pixels is equal to the number of the required LED chips. The LED chips cannot be directly formed on an array substrate of the display apparatus through the thin film and the patterning processes, but need to be electrically coupled to the corresponding electrodes of the array substrate through transfer and bonding, so that the number of LED chips to be transferred correspondingly increases as the resolution of the display apparatus increases and the number of sub-pixels increases. Accordingly, the number of transfer times increases, the process difficulty increases, and the product yield decreases.

In addition, in the related art, each LED chip has only one epitaxial structure, and thus only can emit light of one color. In order to achieve multi-color display of the LED display apparatus, the LED chips emitting light of different colors need to be transferred to the driving substrate, and the manufacturing processes and the yield uniformity for the LED chips emitting light of different colors are different; when the LED chips with different qualities are applied to the same display apparatus, the problem of uneven brightness of the display image may be caused.

In order to solve at least one technical problem of the related art, the embodiments of the present disclosure provide a corresponding solution.

The LED chip in the present disclosure may be a mini light-emitting diode (Mini LED) chip or a micro light-emitting diode (Micro LED) chip.

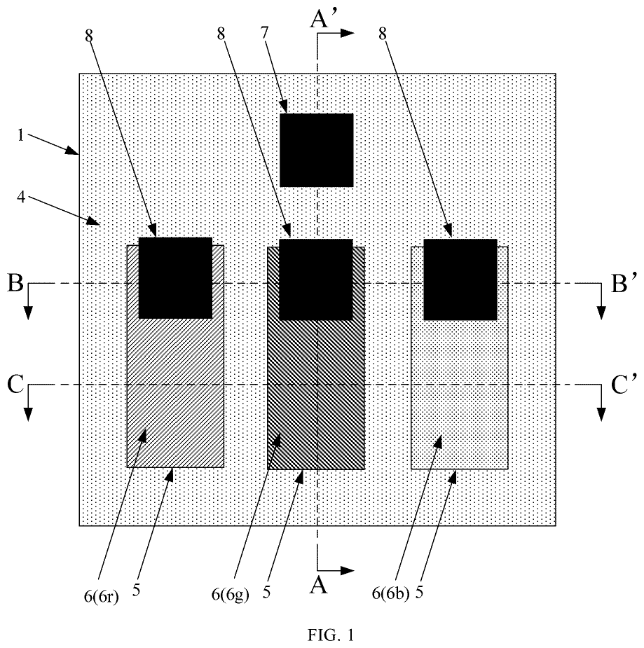

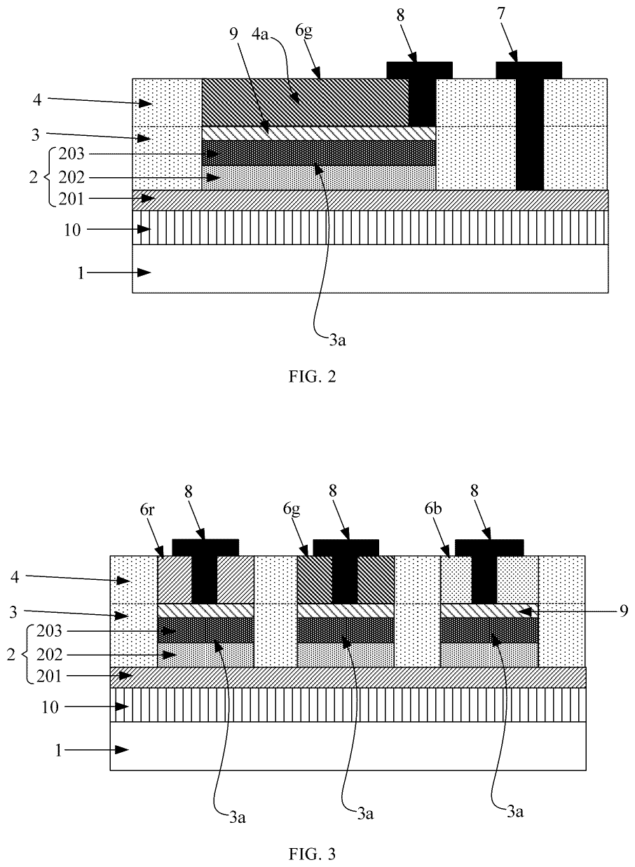

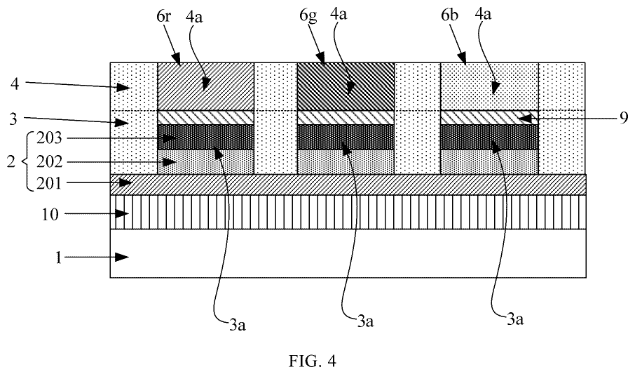

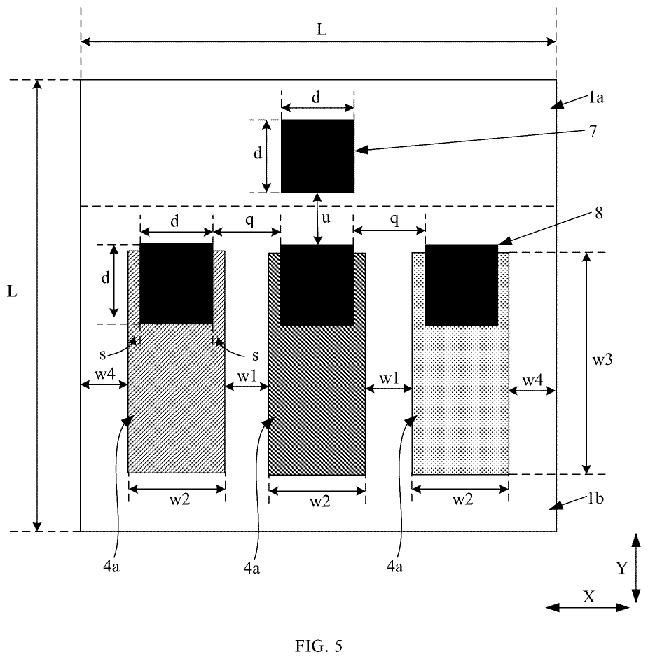

FIG. 1 is a schematic top view of an LED chip according to an embodiment of the present disclosure; FIG. 2 is a schematic cross-sectional view taken along a line A-A′ of FIG. 1; FIG. 3 is a schematic cross-sectional view taken along a line B-B′ of FIG. 1; FIG. 4 is a schematic cross-sectional view taken along a line C-C′ of FIG. 1. As shown in FIGS. 1 to 4, the LED chip may include: a substrate 1, a plurality of epitaxial structures 2, a first light-blocking layer 3, a second light-blocking layer 4, at least one first electrode 7 and a plurality of second electrodes 8.

The plurality of epitaxial structures 2 are located on one side of the substrate 1, a gap exists between any two adjacent epitaxial structures 2, each epitaxial structure 2 includes a first semiconductor pattern, a light-emitting pattern 202 and a second semiconductor pattern 203 which are sequentially stacked, and the first semiconductor patterns of the plurality of epitaxial structures 2 are coupled to each other to form a first semiconductor layer 201.

The first light-blocking layer 3 is located on a side of the first semiconductor layer 201 away from the substrate 1, and is provided therein with a plurality of accommodating holes 3a in one-to-one correspondence with the epitaxial structures 2, and the light-emitting pattern 202 and the second semiconductor pattern 203 of the epitaxial structure 2 are located in the corresponding accommodating hole 3a.

The second light-blocking layer 4 is located on a side of the first light-blocking layer 3 away from the substrate 1, and is provided therein with a plurality of pixel openings 4a in one-to-one correspondence with the accommodating holes 3a; an orthographic projection of the pixel opening 4a on the substrate 1 overlaps with an orthographic projection of the corresponding accommodating hole 3a on the substrate 1; a light processing pattern 6 is disposed in at least one pixel opening 4a; at least one light processing pattern 6 includes a color conversion pattern 6r/6g, which is configured to convert light of a preset color emitted by the corresponding light-emitting pattern 202 into light of other color.

The at least one first electrode 7 is electrically coupled to the first semiconductor layer 201.

The plurality of second electrodes 8 are in one-to-one correspondence with the epitaxial structures 2, and are electrically coupled to the second semiconductor patterns 203 of the corresponding epitaxial structures 2.

In the embodiment of the present disclosure, one first semiconductor layer 201 may be electrically coupled to one or more first electrodes 7, and each second electrode 8 is electrically coupled to one corresponding second semiconductor pattern 203.

In some embodiments, the first semiconductor layer 201 and the light-emitting patterns 202 may be in direct contact with each other, and the light-emitting pattern 202 and the second semiconductor pattern 203 may be in direct contact with each other. A material of the first semiconductor layer 201 may be a P-type semiconductor material, and correspondingly, a material of the second semiconductor patterns 203 may be an N-type semiconductor material. Alternatively, the material of the first semiconductor patterns may be an N-type semiconductor material, and accordingly, the material of the second semiconductor patterns 203 may be a P-type semiconductor material. The light-emitting patterns 202 may be a multiple quantum well (MQW) layer. For example, the material of the light-emitting patterns 202 may be gallium nitride (GaN).

In practical applications, the materials of the first semiconductor layer 201 and the second semiconductor patterns 203 include a plurality of materials, which may be selected according to practical requirements. For example, intrinsic semiconductor materials in the first semiconductor patterns and the second semiconductor patterns 203 are the same, and may be any one of GaN, gallium phosphide (GaP), aluminum gallium arsenide (AlGaAs), and aluminum gallium indium phosphide (AlGaInP). In a case where different voltages are applied to the first semiconductor layer 201 and the second semiconductor patterns 203, respectively, to form an electric field therebetween, if the intrinsic semiconductor materials in the first semiconductor layer 201 and the second semiconductor patterns 203 are both GaN, the epitaxial structures 2 may emit green or blue light; if the intrinsic semiconductor materials in the first semiconductor layer 201 and the second semiconductor patterns 203 are GaP, AlGaAs, or AlGaInP, the epitaxial structures 2 may emit red light.

It should be noted that in the case where different voltages are applied to the first semiconductor layer 201 and the second semiconductor patterns 203, respectively, to form an electric field therebetween, that is, a PN junction having a potential barrier is formed between the first semiconductor patterns and the second semiconductor patterns 203, when minority carriers and majority carriers are combined in an overlapping region of the first semiconductor layer 201, the corresponding light-emitting pattern 202, and the corresponding second semiconductor pattern 203 in the stacking direction, the excess energy is released in the form of light, and the electric energy is directly converted into the light energy. Therefore, the overlapping region of the first semiconductor layer 201, the light-emitting pattern 202, and the second semiconductor pattern 203 in the stacking direction is substantially a light-emitting region of the epitaxial structure 2, and an area of the overlapping region of the first semiconductor layer 201, the light-emitting pattern 202, and the second semiconductor pattern 203 in the stacking direction is substantially a light-emitting area of the epitaxial structure 2.

In the embodiment of the present disclosure, any two adjacent epitaxial structures 2 of the plurality of epitaxial structures 2 on the same LED chip have a gap therebetween, which means that each epitaxial structure 2 may have an independent light-emitting region. The LED chip includes the plurality of epitaxial structures 2, so that the LED chip has a plurality of independent light-emitting regions. In the case of applying the LED chip to the display apparatus, one or more light-emitting regions (e.g., two or three, etc.) of the LED chip may correspond to one sub-pixel of the display apparatus, which means that one LED chip may correspond to a plurality of sub-pixels of the LED display apparatus. Therefore, in the process of transferring the LED chips, transferring one LED chip may be equivalent to transferring an LED chip corresponding to the plurality of sub-pixels. Compared with the case in the related art where it needs to transfer one LED chip for each sub-pixel, the solution of the present disclosure can effectively reduce the number of the LED chips to be transferred, thereby effectively reducing the transfer times, reducing the process difficulty and improving the product yield.

Meanwhile, by providing the second light-blocking layer 4 on a side of the epitaxial structures 2 away from the substrate 1 and providing the color conversion patterns 6r and 6g in at least a portion of the pixel openings 4a, the light of different colors can be emitted through the pixel openings 4a corresponding to different epitaxial structures 2, that is, the light of different colors can be emitted through the pixel openings 4a corresponding to different epitaxial structures 2 under the condition that the epitaxial structures 2 on the same LED chip have the same quality, so as to meet the requirements on multi-color and even full-color display of the display apparatus.

In the embodiment of the present disclosure, a material of the color conversion patterns 6r and 6g is a wavelength conversion material, such as a cadmium compound quantum dot, an indium compound quantum dot, a perovskite type quantum dot, a rare earth phosphor, an organic fluorescent material, etc., and the light emitted from the epitaxial structures 2 is converted into the light of other colors by means of the wavelength conversion property of the wavelength conversion material, thereby realizing a multi-color and even full-color display.

Three epitaxial structures 2, three pixel openings 4a and the color conversion patterns 6r, 6g arranged in two pixel openings 4a are only exemplarily illustrated in FIGS. 1 to 4, which is only for illustrative purposes, and does not limit the technical solution of the present disclosure.

In the embodiment of the present disclosure, a shape of an orthographic projection of each epitaxial structure 2 on the substrate 1 may include at least one of a polygon (e.g., a triangle, a rectangle, a hexagon, etc.), a circle, and an ellipse. A shape of an orthographic projection of the pixel opening 4a corresponding to the epitaxial structure 2 on the substrate 1 may include at least one of a polygon (e.g., a triangle, a rectangle, a hexagon, etc.), a circle, and an ellipse.

In addition, the first light-blocking layer 3 is arranged between the adjacent epitaxial structures 2, so that the problem of light crosstalk between the adjacent epitaxial structures 2 can be effectively avoided; meanwhile, the second light-blocking layer 4 is arranged between the adjacent pixel openings 4a, so that the problem of color mixing of light of different colors in the pixel openings 4a can be effectively avoided. In the embodiment of the present disclosure, by combining the first light-blocking layer 3 and the second light-blocking layer 4, light emitted by each epitaxial structure 2 can be effectively prevented from reaching other pixel opening 4a not corresponding to the epitaxial structure 2, so as to avoid the problem of the light crosstalk caused by the superimposing of light from different epitaxial structures 2 in the same pixel opening 4a.

In the embodiment of the present disclosure, the materials of the first light-blocking layer 3 and the second light-blocking layer 4 may be respectively selected from one of a light-absorbing material and a light-reflecting material. The light-absorbing material includes a light-absorbing material of a dark color such as black, green, blue or the like.

When the first light-blocking layer 3 and/or the second light-blocking layer 4 are made of the light-reflecting material, the problems of the light crosstalk and the color mixing can be avoided, and the light-emitting efficiency of the product can be improved effectively.

In some embodiments, the materials of the first light-blocking layer 3 and the second light-blocking layer 4 are the same, so that the first light-blocking layer 3 and the second light-blocking layer 4 may have a one-piece structure, thereby simplifying the manufacturing process for the LED chip.

In some embodiments, the orthographic projection of the pixel opening 4a on the substrate 1 completely covers the orthographic projection of the corresponding accommodating hole 3a on the substrate 1, so as to ensure that the light emitted by the light-emitting pattern 202 in the accommodating hole 3a can reach the corresponding pixel opening 4a as much as possible. As an alternative embodiment, the orthographic projection of the pixel opening 4a on the substrate 1 completely overlaps with the orthographic projection of the corresponding accommodating hole 3a on the substrate 1.

In some embodiments, the at least one first electrode 7 is located on a side of the second light-blocking layer 4 away from the substrate 1, and is coupled to and in contact with the first semiconductor layer 201 in a via manner.

In some embodiments, each epitaxial structure 2 further includes an ohmic contact pattern 9 located on a side of the second semiconductor pattern 203 away from the substrate 1, the ohmic contact pattern 9 is located in the corresponding accommodating hole 3a; the second electrodes 8 are located on a side of the second light-blocking layer 4 away from the substrate 1, and each second electrode 8 is coupled to and in contact with the ohmic contact pattern 9 of the corresponding epitaxial structure 2 in a via manner.

In the embodiment of the present disclosure, by providing the ohmic contact pattern 9 between the second electrode 8 and the second semiconductor pattern 203, the second electrode 8 is electrically coupled to the corresponding second semiconductor pattern 203 through the ohmic contact pattern 9. In some embodiments, orthographic projections of the ohmic contact pattern 9 and the corresponding second semiconductor pattern 203 on the substrate 1 coincide with each other or substantially coincide with each other, so that the mobility of carriers (e.g., holes) can be effectively increased by the ohmic contact pattern 9. A material of the ohmic contact pattern 9 includes various materials, and may be selected according to actual needs. In some embodiments, the material of the ohmic contact pattern 9 may be a material having a relatively high light transmittance, such as indium tin oxide.

In some embodiments, the light processing pattern 6 is disposed within each pixel opening 4a; the light processing patterns 6 in a portion of the pixel openings 4a are color conversion patterns 6r and 6g, the light processing patterns 6 in the other portion of the pixel openings 4a are light transmission patterns 6b, and the light transmission patterns 6b are configured to allow light of a preset color to pass therethrough.

Since the light emitted from the color conversion patterns 6r and 6g is scattered all around, an angular spectrum for the light emitted at the pixel openings 4a where the color conversion patterns 6r and 6g are disposed have a wide-range distribution, while an angular spectrum for the light emitted at the pixel openings 4a where the color conversion patterns 6r and 6g are not disposed have a small-range distribution. That is, the angular spectrum for the light emitted at the pixel openings 4a where the color conversion patterns 6r and 6g are disposed is inconsistent with the an angular spectrum for the light emitted at the pixel openings 4a where the color conversion patterns 6r and 6g are not disposed, thereby affecting the display quality. To solve the above technical problem, in some embodiments, each light transmission pattern 6b includes a light field modulation pattern configured to adjust the angular spectrum for the light of the preset color emitted at the pixel opening 4a, so that the angular spectrum for the light emitted at the pixel openings 4a where the color conversion patterns 6r and 6g are disposed is consistent with the angular spectrum for the light emitted at the pixel openings 4a where the color conversion patterns 6r and 6g are not disposed, thereby improving the display quality. In some embodiments, a material of the light field modulation pattern includes a nanoparticle material such as TiOx, SiOx, CrOx, etc.; that is, in practical applications, the nanoparticle material such as TiOx, SiOx, CrOx, etc. may be deposited in the pixel openings 4a where the color conversion patterns 6r, 6g are not disposed, to obtain the light field modulation pattern.

In some embodiments, each first electrode 7 is in contact with the first semiconductor layer through a first connection hole 11 in the first light-blocking layer 3 and the second light-blocking layer 4; each second electrode 8 is in contact with the second semiconductor pattern 203 of the corresponding epitaxial structure 2 through a connection hole in the corresponding light processing pattern 6.

In some embodiments, the at least one first electrode 7 and the plurality of second electrodes 8 are provided in the same layer.

The “same layer” described in the present disclosure refers to a layer structure formed by the following steps: forming a film layer for forming a specific pattern using the same film forming process; and then performing a single patterning process using the same mask plate. Depending on the specific pattern, the single patterning process may include multiple exposure, development or etching processes, and the specific patterns in the formed layer structure may be continuous or discontinuous, and the specific patterns may be at different heights or have different thicknesses. Thus, the at least one first electrode 7 and the plurality of second electrodes 8 may be simultaneously formed by one patterning process, thereby simplifying the manufacturing process for the LED chip.

In some embodiments, the light of the preset color is blue light, i.e., the light emitted by the epitaxial structure 2 is blue light; the light of other colors includes at least one of red light, green light, cyan light, magenta light, and yellow light, that is, any one of the color conversion patterns 6r, 6g may obtain any one of red light, green light, cyan light, magenta light, or yellow light through the conversion.

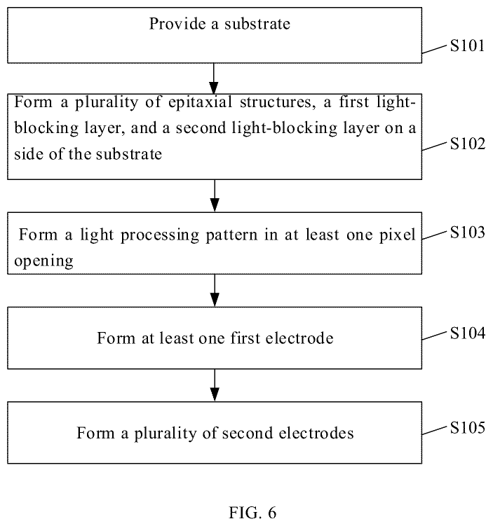

FIG. 5 is a schematic diagram showing a size of an LED chip according to an embodiment of the present disclosure. As an alternative, as shown in FIG. 5, the substrate 1 includes a first region la and a second region b arranged in a second direction; the first electrode 7 is located in the first region 1a; the plurality of epitaxial structures 2 are positioned in the second region 1b and are sequentially arranged in the second region 1b along a first direction X; the plurality of pixel openings 4a corresponding to the plurality of epitaxial structures 2 are located in the second region 1b and are sequentially arranged in the second region 1b along the first direction X; an orthographic projection of each second electrode 8 on the substrate 1 overlaps with an orthographic projection of the pixel opening 4a of the corresponding epitaxial structure 2 on the substrate 1, and is located at one end, which is close to the first region 1a, of the orthographic projection of the pixel opening 4a of the corresponding epitaxial structure 2 on the substrate 1.

In some embodiments, a length of each light-emitting pattern 202 in the first direction X is in a range from 10 μm to 100 μm; a length of each light-emitting pattern 202 in the second direction Y is in a range from 30 μm to 200 μm.

In some embodiments, only one first electrode 7 is provided, and is located at the middle position of the first region la in the first direction X; the plurality of pixel openings 4a corresponding to the plurality of epitaxial structures 2 are arranged at equal intervals along the first direction X in the second region 1b; the second electrodes 8 corresponding to the plurality of epitaxial structures 2 are arranged at equal intervals along the first direction X in the second region 1b.

The first direction X intersects the second direction Y. As an alternative embodiment, the first direction X is perpendicular to the second direction Y. For example, the first direction X is a row direction in FIG. 5, and the second direction Y is a column direction in FIG. 5.

In the embodiment shown in FIG. 5, three epitaxial structures 2 are provided, and three pixel openings 4a are correspondingly provided; for the three epitaxial structures 2, one first electrode 7 and three second electrodes 8 are provided.

As a specific example, as shown in FIG. 5, a length L of the LED chip in the first direction X and a length L of the LED chip in the second direction Y are both 318 um, a length w2 of each pixel opening 4a in the first direction X is 70 μm, a length w3 of each pixel opening in the second direction Y is 120 μm; a distance w4 between each of the two pixel openings 4a located on the outer side and an edge of the LED chip closest to the pixel opening 4a in the first direction X is 27 μm, and a distance w1 between the two adjacent pixel openings 4a in the first direction X is 27 μm; a length d of each of the first electrode 7 and the second electrode 8 in the first direction X and a length d of each of the first electrode 7 and the second electrode 8 in the second direction Y are both 50 μm, a distance q between any two adjacent second electrodes 8 in the first direction X is 47 μm, a connection line between a center point of the first electrode 7 and a center point of a second electrode 8 of the three second electrodes 8 located in the middle extends along the second direction Y, and a distance u between the first electrode 7 and the second electrode 8 of the three second electrodes 8 located in the middle in the second direction Y is 47 μm. Each of two edges of each second electrode 8 opposite to each other along the first direction X and the edge of the corresponding pixel opening 4a adjacent to the edge of the second electrode 8 in the first direction X have a distance s of 10 μm therebetween.

It should be noted that the sizes and distributions of the pixel openings 4a, the first electrode 7 and the second electrodes 8 shown in FIG. 5 are only exemplary, and do not limit the technical solution of the present disclosure.

With continued reference to FIGS. 2 to 4, in some embodiments, a buffer layer 10 is also disposed between the first semiconductor layer 201 and the substrate 1.

In the related art, the lattice coefficients and the thermal expansion coefficients of the first semiconductor layer 201 and the substrate 1 are largely different from each other, so that it is difficult to directly form a high-quality first semiconductor layer 201 on the substrate 1. In the embodiment of the present disclosure, by providing the buffer layer 10 between the first semiconductor layer 201 and the substrate 1, the film forming quality of the first semiconductor layer 201 can be effectively improved. A material of the buffer layer 10 may be selected according to the materials of the substrate 1 and the first semiconductor layer 201. For example, the material of the first semiconductor layer 201 is GaN, the substrate 1 is a sapphire substrate 1, so that the material of the buffer layer 10 may be AlN or ZnO. In a case where the material of the buffer layer 10 is AlN, AlN and GaN belong to the same material system, lattice mismatch is only 2%, thermal expansion coefficients are similar, and a mobility of carries in a GaN material grown on the AlN buffer layer 10 is increased by nearly 10 times as compared with a mobility of carries in a GaN material grown directly on the sapphire substrate 1.

Based on the same inventive concept, the embodiments of the present disclosure further provide a method for manufacturing an LED chip, which can be used for manufacturing the LED chip provided in the foregoing embodiments, and will be described in detail with reference to the accompanying drawings.

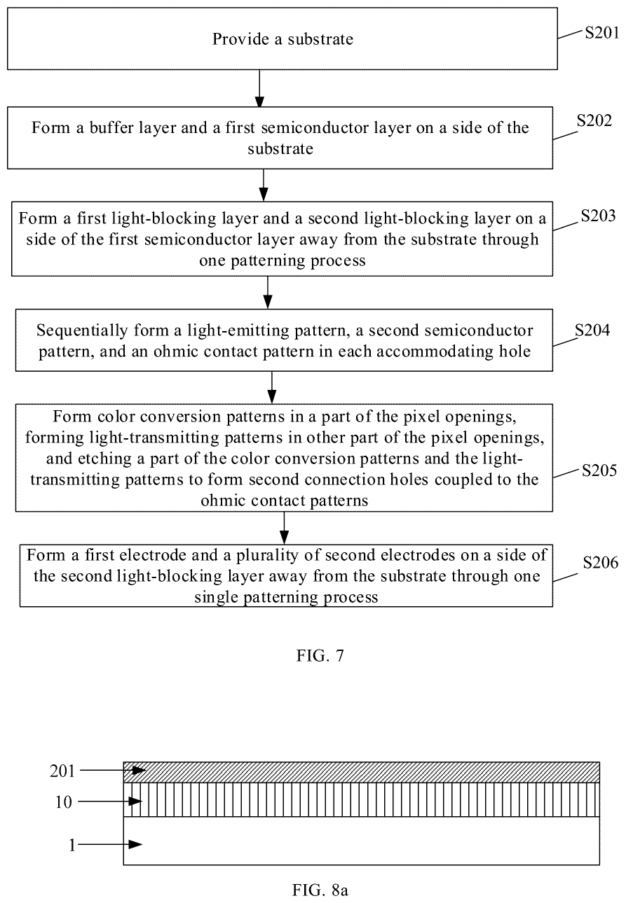

FIG. 6 is a flowchart of a method for manufacturing an LED chip according to an embodiment of the present disclosure. As shown in FIG. 6, the method includes Steps S101 to S105.

Step S101 includes providing a substrate.

Step S102 includes forming a plurality of epitaxial structures, a first light-blocking layer, and a second light-blocking layer on one side of the substrate.

A gap exists between any two adjacent epitaxial structures, each epitaxial structure includes a first semiconductor pattern, a light-emitting pattern and a second semiconductor pattern which are sequentially stacked, and the first semiconductor patterns of the plurality of epitaxial structures are coupled to each other to form a first semiconductor layer. The first light-blocking layer is located on a side of the first semiconductor layer away from the substrate, and is provided therein with a plurality of accommodating holes in one-to-one correspondence with the epitaxial structures, and the light-emitting patterns and the second semiconductor patterns of the epitaxial structures are located in the corresponding accommodating holes. The second light-blocking layer is located on a side of the first light-blocking layer away from the substrate, and is provided therein with a plurality of pixel openings in one-to-one correspondence with the accommodating holes; an orthographic projection of the pixel opening on the substrate overlaps with an orthographic projection of the corresponding accommodating hole on the substrate.

Step S103 includes forming a light processing pattern in at least one pixel opening.

The at least one light processing pattern includes a color conversion pattern, which is configured to convert light of a preset color emitted by the corresponding light-emitting pattern into light of other color.

Step S104 includes forming at least one first electrode.

The at least one first electrode is electrically coupled to the first semiconductor layer.

Step S105 includes forming a plurality of second electrodes.

The plurality of second electrodes are in one-to-one correspondence with the epitaxial structures, and are electrically coupled to the second semiconductor patterns of the corresponding epitaxial structures.

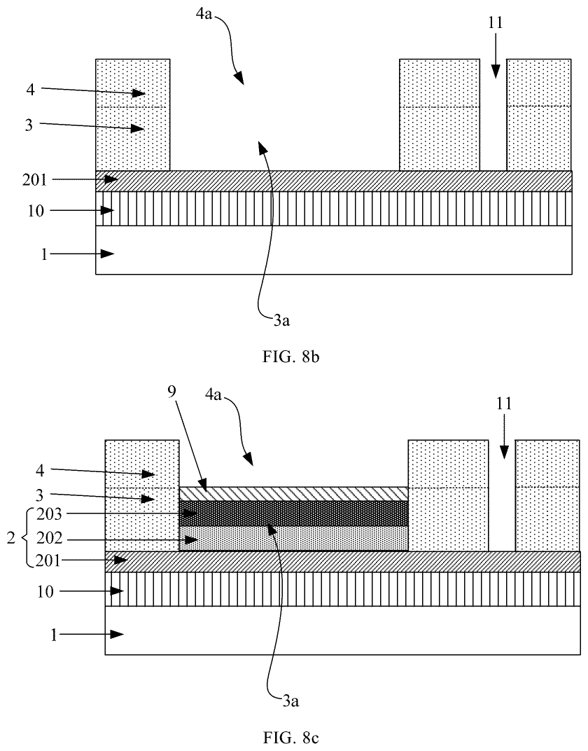

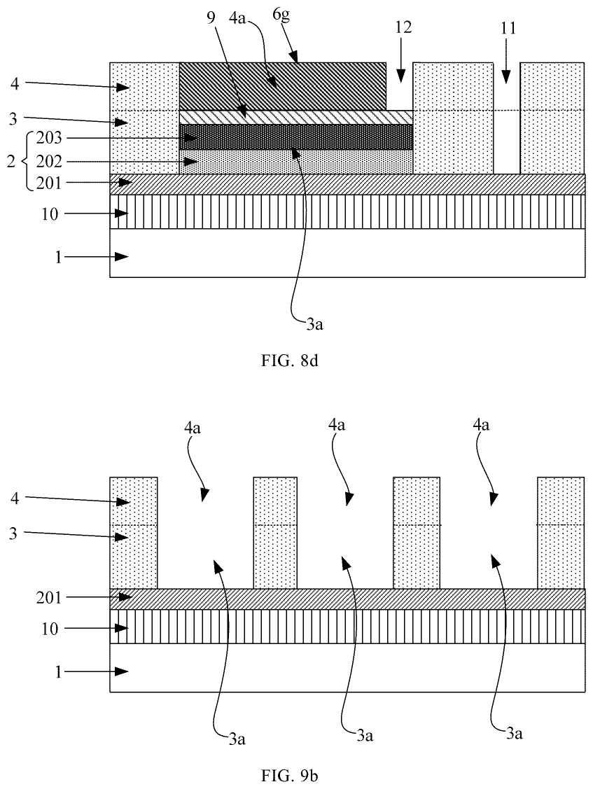

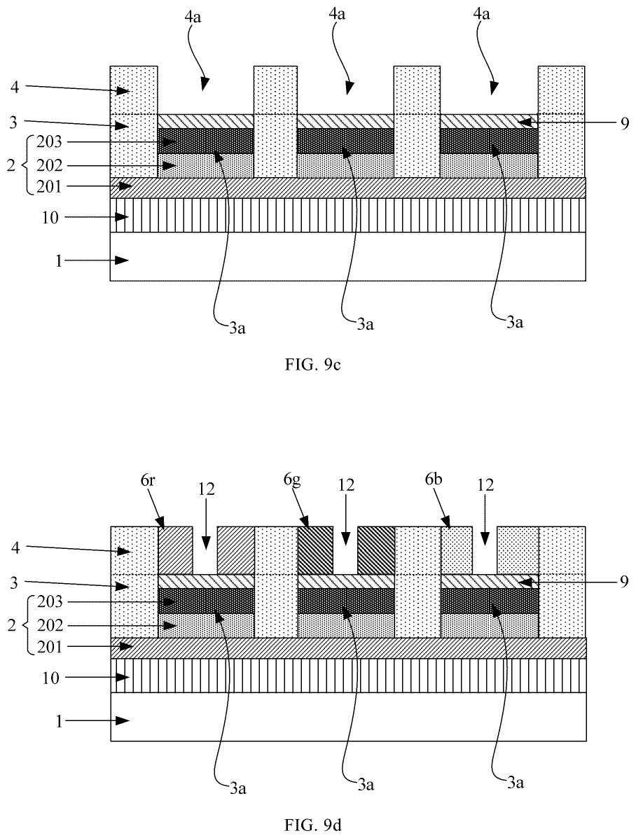

FIG. 7 is a flowchart of another method for manufacturing an LED chip according to an embodiment of the present disclosure; FIGS. 8a to 8d are schematic cross-sectional views of intermediate products obtained by using the manufacturing method shown in FIG. 7; FIGS. 9b to 9d are other schematic cross-sectional views of intermediate products obtained by using the manufacturing method shown in FIG. 7. It should be noted that FIGS. 8a to 8d are schematic cross-sectional views of the intermediate products corresponding to the cross-sectional view taken along a line A-A′ of FIG. 1, and FIGS. 9b to 9d are schematic cross-sectional views of the intermediate products corresponding to the cross-sectional view taken along a line B-B′ of FIG. 1. As shown in FIGS. 7 to 9d, the manufacturing method includes Steps S201 to S206.

Step S201 includes providing a substrate.

The substrate may include various types, and for example, the substrate may be a GaP substrate, a GaAs substrate, a silicon substrate, a silicon carbide substrate, a sapphire substrate, or the like.

It should be noted that the type of the substrate may be determined according to the material of the first semiconductor pattern and the second semiconductor pattern to be formed. For example, in the case where the intrinsic semiconductor material in the first and second semiconductor patterns is GaP, AlGaAs, AlGaInP, or the like, the substrate may be a GaP substrate or a GaAs substrate. In the case where the intrinsic semiconductor material in the first and second semiconductor patterns is GaN, the substrate may be a silicon carbide substrate, a sapphire substrate, or the like.

Step S202 includes forming a buffer layer and a first semiconductor layer on one side of the substrate.

A material of the buffer layer 10 may be selected according to the materials of the substrate 1 and the first semiconductor layer 201 to be formed.

Referring to FIG. 8a, for example, a first semiconductor material film may be epitaxially grown on a side of the buffer layer 10 away from the substrate 1 by using a metalorganic vapor phase epitaxy (MOCVD) process.

Step S203 including forming a first light-blocking layer and a second light-blocking layer on a side of the first semiconductor layer away from the substrate through one patterning process.

Referring to FIG. 8b and FIG. 9b, for example, a light-blocking material film, which may be a light-absorbing material film or a light-reflecting material film, is formed firstlone-y; then, one patterning process is performed on the light-blocking material film once to simultaneously form the first light-blocking layer 3 and the second light-blocking layer 4. The first light-blocking layer 3 and the second light-blocking layer 4 are formed as a single piece.

A plurality of accommodating holes 3a in one-to-one correspondence with the epitaxial structures 2 are formed in the first light-blocking layer 3, a plurality of pixel openings 4a in one-to-one correspondence with the epitaxial structures 2 are formed in the second light-blocking layer 4, and the pixel openings 4a are communicated with the corresponding accommodating holes 3a. In addition, a first connection hole 11 is formed in the first light-blocking layer 3 and the second light-blocking layer, the first electrode 7 is coupled to the first semiconductor layer 201 through the first connection hole 11, and the first connection hole 11 is communicated with the first semiconductor layer 201.

Step S204 includes sequentially forming a light-emitting pattern, a second semiconductor pattern, and an ohmic contact pattern in each accommodating hole.

Referring to FIGS. 8c and 9c, the light-emitting pattern 202 and the second semiconductor pattern 203 may be epitaxially grown sequentially in each of the accommodating holes 3a, for example, using an MOCVD process.

Here, for the materials of the first semiconductor layer 201, the light-emitting pattern 202 and the second semiconductor pattern 203, reference may be made to the description of the materials of the first semiconductor pattern, the light-emitting pattern 202 and the second semiconductor pattern 203 in the foregoing embodiments, and details thereof are not repeated here.

For example, after the fabrication of the second semiconductor pattern 203 is completed, a fine metal mask (FMM) may be supported by the second light-blocking layer 4 and the ohmic contact pattern 9 may be formed in each of the accommodating holes 3a through an evaporation process. A material of the ohmic contact pattern 9 is a material having a high light transmittance, such as indium tin oxide.

Step S205 includes forming color conversion patterns in a portion of the pixel openings, forming light-transmitting patterns in other portions of the pixel openings, and etching a part of the color conversion patterns and the light-transmitting patterns to form second connection holes coupled to the ohmic contact patterns.

Referring to FIGS. 8d and 9d, the material of the color conversion patterns 6r and 6g is a wavelength conversion material, such as a cadmium compound quantum dot, an indium compound quantum dot, a perovskite type quantum dot, a rare earth phosphor, an organic fluorescent material, etc., and the light emitted from the epitaxial structures 2 is converted into the light of other colors by means of the wavelength conversion property of the wavelength conversion material, thereby realizing a multi-color and even full-color display. It should be noted that the light of other colors obtained through the conversion by the color conversion patterns 6r and 6g disposed in the different pixel openings 4a may be the light of same color or light of different colors, which may be selected and provided according to actual needs.

A material of the light-transmitting pattern 6b is a material capable of allowing the light of the preset color emitted by the corresponding light-emitting pattern 202 to pass therethrough.

After the manufacturing of the color conversion patterns 6r and 6g and the light-transmitting patterns 6b is completed, the color conversion patterns 6r and 6g and the light-transmitting patterns 6b are etched by an etching process to form corresponding second connection holes 12, which are communicated with the ohmic contact patterns 9.

As one example, the LED chip has a blue pixel unit, a green pixel unit, and a red pixel unit. In this case, the light-emitting pattern 202 in the epitaxial structure 2 may be an electroluminescent material emitting blue light; the light-transmitting pattern 6b (a light field modulation pattern) is formed in the pixel opening 4a corresponding to the blue pixel unit, the color conversion pattern 6r capable of converting blue light into red light is formed in the pixel opening 4a corresponding to the red pixel unit, and the color conversion pattern 6g capable of converting blue light into green light is formed in the pixel opening 4a corresponding to the green pixel unit.

Step S206 includes forming a first electrode and a plurality of second electrodes on a side of the second light-blocking layer away from the substrate through one single patterning process.

Referring to FIGS. 2 to 4, for example, a conductive material film, specifically, a metal material film, is formed firstly, and the metal material may be a metal Ti, Al, Ni, Au, Cu, In, Ag, Sn, or the like or an alloy thereof; then, the conductive material film is patterned to simultaneously obtain patterns of the first electrode 7 and the second electrodes 8, wherein the first electrode 7 is in contact with the first semiconductor layer 201 through the first connection hole 11, and each second electrode 8 is in contact with the corresponding second semiconductor pattern 203 through the second connection hole 12.

Based on the same inventive concept, the embodiment of the present disclosure further provides a display apparatus, which will be described in detail below with reference to the accompanying drawings.

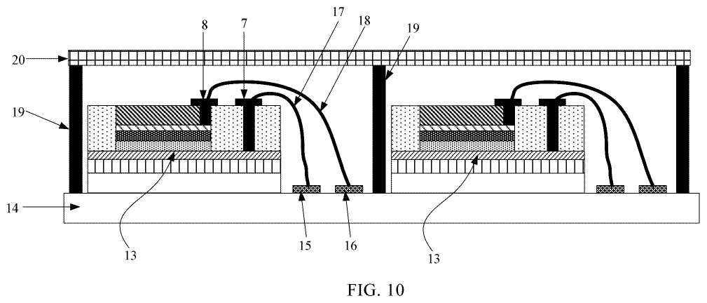

FIG. 10 is a schematic cross-sectional view of a display apparatus according to an embodiment of the present disclosure. As shown in FIG. 10, the display apparatus includes: a driving back plate 14 and a plurality of LED chips 13. The LED chip 13 provided in the above embodiment is adopted as the LED chip 13, and for the specific description of the LED chip 13, reference may be made to the contents in the foregoing embodiments, which is not described here.

The driving back plate 14 includes a plurality of connection pads including a plurality of first pads 15 and a plurality of second pads 16; each first electrode 7 in the light-emitting diode chip is electrically coupled to a corresponding first pad 15, and each second electrode 8 in the light-emitting diode chip is electrically coupled to a corresponding second pad 16.

In some embodiments, each first electrode 7 and each second electrode 8 are located on a side of the second light-blocking layer away from the driving back plate 14; each first electrode 7 is coupled to the corresponding first pad 15 through a first conductive lead 17; each second electrode 8 is coupled to the corresponding second pad 16 through a second conductive lead 18. That is, the plurality of LED chips 13 are fixed on the driving back plate 14 in a normal chip manner.

In some embodiments, the display apparatus further includes: a third light-blocking layer 19 and an encapsulation layer 20.

The third light-blocking layer 19 is located between any two adjacent LED chips 13; the arrangement of the third light-blocking layer 19 may effectively avoid crosstalk of emitted light between adjacent LED chips 13.

The encapsulation layer 20 is positioned on a side of the third light-blocking layer 19 and the plurality of LED chips 13 away from the driving back plate 14; the encapsulating layer 20 and the third light-blocking layer 19 can jointly realize the integral encapsulation of the LED chips 13 in the display apparatus, so as to isolate water and oxygen and ensure the stable operation of the color conversion patterns.

As one example, the encapsulation layer 20 may be a stacked structure formed by alternately disposing organic encapsulation layers 20 and inorganic encapsulation layers 20.

As another example, the encapsulation layer 20 is formed by drying and curing a glue, the glue may automatically fill the gaps between the LED chips 13 when the glue is applied, and after the drying and curing are completed, the encapsulation layer 20 can play a role in isolating water and oxygen and fixing the LED chips 13.

In some embodiments, the number of the first electrodes 7 is less than the number of the second electrodes 8 in each LED chip 13, and the number of the first pads 15 electrically coupled to the first electrodes 7 may be less than the number of the second pads 16 electrically coupled to the second electrodes 8. For example, each LED chip 13 has one first electrode 7 and a plurality of second electrodes 8. In this case, each first pad 15 may correspond to the plurality of second pads 16 and the first pad 15 and the plurality of second pads 16 may be classified into one group, and may be electrically coupled to one LED chip 13.

In some embodiments, the driving back plate 14 is configured to transport electrons to the first electrode 7 of the LED chip 13 electrically coupled to the first pad 15 through the first pad 15 and to transport holes to one second electrode 8 of the plurality of second electrodes 8 of the LED chip 13 electrically coupled to the corresponding second pad 16 through the second pad 16, so that the electrons and the holes are recombined to emit light in the light-emitting pattern 202 in the corresponding epitaxial structure 2.

It should be noted that the display apparatus provided in the embodiment of the present disclosure is different from that in the related art, in that each pixel is an independent structure, instead of an array structure formed by sequentially stacking materials for the film layers and patterning the materials through a thin film process on a large-sized substrate.

The display apparatus provided by the embodiments of the present disclosure has the same beneficial effects as the LED chips according to some embodiments described above, and the details are not repeated herein.

In some embodiments, the driving back plate may be, for example, a back plate in a backlight module of a liquid crystal display (LCD). In this case, the LED chip may be used as a light source, and the display apparatus may be used as a backlight module in the LCD to provide the backlight to the LCD for the image display.

In other embodiments, the driving back plate may be a display back plate, for example. In this case, the LED chip 20 may be used as a part of the plurality of sub-pixels, and the display apparatus may be used as an LED display apparatus for the image display. The display apparatus may be a mini LED display apparatus or a micro LED display apparatus.

In some embodiments, the display apparatus is any product or component having a display function, such as a mobile phone, a tablet computer, a television, a display, a notebook computer, a digital photo frame, a navigator, or the like.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A light-emitting diode chip, comprising:
a substrate;
a plurality of epitaxial structures on a side of the substrate, wherein a gap exists between any two adjacent ones of the plurality of epitaxial structures, each epitaxial structure comprises a first semiconductor pattern, a light-emitting pattern and a second semiconductor pattern which are sequentially stacked, and the first semiconductor patterns of the plurality of epitaxial structures are coupled to each other to form a first semiconductor layer;
a first light-blocking layer on a side of the first semiconductor layer away from the substrate, wherein the first light-blocking layer is provided therein with a plurality of accommodating holes in one-to-one correspondence with the plurality of epitaxial structures, and the light-emitting patterns and the second semiconductor patterns of the plurality of epitaxial structures are in corresponding ones of the plurality of accommodating holes;
a second light-blocking layer on a side of the first light-blocking layer away from the substrate, wherein the second light-blocking layer is provided therein with a plurality of pixel openings in one-to-one correspondence with the plurality of accommodating holes; an orthographic projection of each pixel opening on the substrate overlaps with an orthographic projection of the corresponding accommodating hole on the substrate; a light processing pattern is in at least one pixel opening and includes a color conversion pattern configured to convert light of a preset color emitted by the light-emitting pattern into light of other color;
at least one first electrode electrically coupled to the first semiconductor layer; and
a plurality of second electrodes in one-to-one correspondence with the plurality of epitaxial structures and electrically coupled to the second semiconductor patterns of corresponding ones of the plurality of epitaxial structures.

2. The light-emitting diode chip according to claim 1, wherein the first light-blocking layer and the second light-blocking layer have one-piece structure.

3. The light-emitting diode chip according to claim 1, wherein the orthographic projection of each pixel opening on the substrate completely covers the orthographic projection of the corresponding accommodating hole on the substrate.

4. The light-emitting diode chip according to claim 1, wherein the at least one first electrode is on a side of the second light-blocking layer away from the substrate, and is coupled to and in contact with the first semiconductor layer in a via manner.

5. The light-emitting diode chip according to claim 4, wherein each epitaxial structure further comprises an ohmic contact pattern on a side of the second semiconductor pattern away from the substrate, the ohmic contact pattern is in the corresponding accommodating hole; and
the plurality of second electrodes are on the side of the second light-blocking layer away from the substrate, and each second electrode is coupled to and in contact with the ohmic contact pattern of the corresponding epitaxial structure in a via manner.

6. The light-emitting diode chip according to claim 5, wherein the light processing pattern is in each pixel opening; and
wherein the light processing pattern in a part of the plurality of pixel openings is the color conversion pattern, and the light processing pattern in other part of the plurality of pixel openings is a light-transmitting pattern configured to allow light of the preset color to pass therethrough.

7. The light-emitting diode chip according to claim 6, wherein the first electrode is in contact with the first semiconductor layer through a first connection hole in the first light-blocking layer and the second light-blocking layer; and
each second electrode is in contact with the ohmic contact pattern of the corresponding epitaxial structure through a second connection hole in the corresponding light processing pattern.

8. The light-emitting diode chip according to claim 5, wherein the at least one first electrode and the plurality of second electrodes are in a same layer.

9. The light-emitting diode chip according to claim 1, wherein the light of the preset color is blue light; and
the light of other color comprises at least one of red light, green light, cyan light, magenta light, and yellow light.

10. The light-emitting diode chip according to claim 1, wherein the substrate comprises a first region and a second region along a second direction;
the at least one first electrode is in the first region;
the plurality of epitaxial structures are in the second region and are sequentially arranged in the second region along a first direction;
the plurality of pixel openings corresponding to the plurality of epitaxial structures are in the second region and are sequentially arranged in the second region along the first direction; and
an orthographic projection of each second electrode on the substrate overlaps with an orthographic projection of the pixel opening of the corresponding epitaxial structure on the substrate, and the orthographic projection of each second electrode on the substrate is at one end, which is close to the first region, of the orthographic projection of the pixel opening of the corresponding epitaxial structure on the substrate.

11. The light-emitting diode chip according to claim 10, wherein the at least one first electrode comprises one first electrode at a middle position of the first region in the first direction;
the plurality of pixel openings corresponding to the plurality of epitaxial structures are arranged at equal intervals along the first direction in the second region; and
the plurality of second electrodes corresponding to the plurality of epitaxial structures are arranged at equal intervals along the first direction in the second region.

12. The light-emitting diode chip according to claim 10, wherein a length of each light-emitting pattern in the first direction is in a range from 10 μm to 100 μm; and
a length of each light-emitting pattern in the second direction is in a range from 30 μm to 200 μm.

13. A method for manufacturing a light-emitting diode chip, wherein the light-emitting diode chip is the light-emitting diode chip according to claim 1, and the method comprises:
providing the substrate;
forming the plurality of epitaxial structures, the first light-blocking layer, and the second light-blocking layer on a side of the substrate;
forming the light processing pattern in at least one pixel opening;
forming the at least one first electrode; and
forming the plurality of second electrodes.

14. The manufacturing method according to claim 13, wherein the first light-blocking layer and the second light-blocking layer have one-piece structure, and the forming the plurality of epitaxial structures, the first light-blocking layer, and the second light-blocking layer on a side of the substrate, comprises:
forming the first semiconductor layer;
forming the first light-blocking layer and the second light-blocking layer on a side of the first semiconductor layer away from the substrate through one patterning process, wherein the plurality of accommodating holes in one-to-one correspondence with the plurality of epitaxial structures are formed in the first light-blocking layer, the plurality of pixel openings in one-to-one correspondence with the plurality of epitaxial structures are formed in the second light-blocking layer, and the pixel openings are communicated with the corresponding accommodating holes;
sequentially forming the light-emitting pattern and the second semiconductor pattern in each accommodating hole; and
forming the light processing pattern in at least one pixel opening.

15. The manufacturing method according to claim 14, wherein the light processing pattern is in each pixel opening; and a part of the light processing patterns is the color conversion pattern, and other part of the light processing patterns is a light-transmitting pattern configured to allow the light of the preset color to pass therethrough; and
the forming the light processing pattern in at least one pixel opening, comprises:
forming the color conversion pattern in a part of the plurality of pixel openings, and forming the light-transmitting pattern in other part of the plurality of pixel openings.

16. The manufacturing method according to claim 14, wherein in the forming the first light-blocking layer and the second light- blocking layer on the side of the first semiconductor layer away from the substrate through one patterning process, a first connection holes communicated with the first semiconductor layer is formed in the first light-blocking layer and the second light-blocking layer;
after the forming the second semiconductor pattern in each accommodating hole and before the forming the light processing pattern in each pixel opening, the method further comprises:
forming an ohmic contact pattern on a side of the second semiconductor pattern away from the substrate in each accommodating hole;
after the forming the light processing pattern in each pixel opening, the method further comprises:
etching a part of each light processing pattern to form a second connection hole coupled to the ohmic contact pattern; and
the forming the at least one first electrode and the forming the plurality of second electrodes comprise:
forming the at least one first electrode and the plurality of second electrodes on the side of the second light-blocking layer away from the substrate through one patterning process, wherein the at least one first electrode is in contact with the first semiconductor layer through the first connection hole, and each second electrode is in contact with a corresponding one of the plurality of second semiconductor patterns through the second connection hole.

17. A display apparatus, comprising:
a driving back plate comprising a plurality of connection pads, wherein the plurality of connection pads comprise a plurality of first pads and a plurality of second pads; and
a plurality of light-emitting diode chips, wherein each light-emitting diode chip is the light-emitting diode chip according to claim 1, each first electrode of the light-emitting diode chip is electrically coupled to a corresponding one of the plurality of first pads, and each second electrode of the light-emitting diode chip is electrically coupled to a corresponding one of the plurality of second pads.

18. The display apparatus according to claim 17, wherein each first electrode and each second electrode are on a side of the second light-blocking layer away from the driving back plate;
each first electrode is coupled to the corresponding first pad through a first conductive lead; and
each second electrode is coupled to the corresponding second pad through a second conductive lead.

19. The display apparatus according to claim 17, further comprising:
a third light-blocking layer between any two adjacent light-emitting diode chips; and
an encapsulation layer on a side of the third light-blocking layer and the light-emitting diode chips away from the driving back plate.

20. The light-emitting diode chip according to claim 1, further comprising a buffer layer between the first semiconductor layer and the substrate.
